(19) United States
(12) Patent Application Publication
(10) Pub. No.: US 2014/0368219 A1
(43) Pub. Date: Dec. 18, 2014

(54) In-Situ Determination of Rod Control System Coil and Cable Impedances for Nuclear Power Plants

(71) Applicant: Analysis and Measurement Services Corporation, Knoxville, TN (US)

(72) Inventors: Gregory W. Morton, Knoxville, TN (US); Samuel D. Caylor, Knoxville, TN (US); Jacob R. McCulley, Knoxville, TN (US); Hashem M. Hashemian, Knoxville, TN (US)

(21) Appl. No.: 13/920,649

(22) Filed: Jun. 18, 2013

(51) Int. Cl. G01R 27/26

(52) U.S. Cl. CPC G01R 27/2611
USPC 324/654

(57) ABSTRACT

Systems and methods of monitoring a rod control system of a nuclear power plant, including calculating impedance of at least one coil of a rod movement mechanism non-intrusively while the system is operating, comparing a measured impedance to a reference impedance, and determining if the measured impedance deviates from the reference impedance value by a predetermined amount to indicate degradation of the rod control system.

### FIELD OF INVENTION

The present application relates generally to rod control systems, and more particularly relates to systems and methods of monitoring rod control systems of nuclear power plants to determine whether the rod control system is operating properly.

### BACKGROUND

In a nuclear Pressurized Water Reactor (PWR), the power level of the reactor is controlled by inserting and retracting control rods, which may include shutdown rods, in a reactor core.

Current designs of many nuclear power plants are equipped with control and shutdown rods which are inserted and withdrawn from the reactor core to control the reactivity by absorbing neutrons. Specifically, in Pressurized Water Reactors (PWRs), the movement of each rod is facilitated by its own electromechanical magnetic jack mechanism located atop the reactor vessel. Two examples of rod control systems that use this mechanism are the Control Rod Drive Mechanism (CRDM) and Control Element Drive Mechanism (CEDM). Both of these mechanisms consist of a set of coils that provide precise vertical movement to the rod by sequentially inducing a magnetic field in the coils to operate the mechanical parts of the system. The magnetic flux provides the energy needed to hold, insert, or withdraw the rod from the reactor core.

Efforts regarding such systems have led to continuing developments to improve their versatility, practicality and efficiency. For example, impedance measurements can be used to verify proper operation of the coils, cables, and connectors that make up the mechanism. Changes in impedance can be used to detect degradation and aging.

### BRIEF SUMMARY

Example embodiments of the present general inventive concept provide systems and methods of systems and methods of monitoring rod control systems of nuclear power plants to determine whether the rod control system is operating properly.

Additional features and embodiments of the present general inventive concept will be set forth in part in the description which follows and, in part, will be obvious from the description, or may be learned by practice of the present general inventive concept.

Example embodiments of the present general inventive concept can be achieved by providing a method of monitoring a rod control system of a nuclear power plant, including calculating impedance of at least one coil of a rod movement mechanism during plant operation using a non-intrusive method for evaluation of the coil(s), comparing a measured impedance to a reference impedance, and determining if the measured impedance deviates from the reference impedance value by a predetermined amount to indicate degradation of the rod control system.

The measuring operation can include analyzing rod control system current and voltage signals of the at least one coil while the system is in operation in the plant.

The measuring operation consists of non-intrusive measurements that do not hinder operations.

The measuring operation can include analyzing the impedance, consisting of resistance and inductance measurements, of any of the coils that make up the rod control mechanism. .

The measurements can determine health of coils, cables, and connectors which together make up the rod control mechanism.

The reference impedance can be based on a recorded impedance of the rod movement mechanism during operation of the nuclear power plant.

Example embodiments of the present general inventive concept can also be achieved by providing a method of monitoring a rod control system of a nuclear power plant, including measuring voltage and current signals of at least one coil of a rod movement mechanism during plant operation using a non-intrusive method for evaluation of the coil(s), calculating an impedance of the least one coil based on measured voltage and current signals, recording a plurality of impedance calculations over a period of time, and determining whether a current recorded impedance changes relative to a prior recorded impedance by a predetermined amount to indicate degradation of the rod control system.

Example embodiments of the present general inventive concept can also be achieved by providing a system to monitor a rod control system of a nuclear power plant, including an impedance determining unit to determine an impedance of at least one coil of a rod movement mechanism during a rod movement sequence of the rod control system, and a controller to compare a measured impedance to a reference impedance, and to determine if the measured impedance deviates from the reference impedance value by a predetermined amount to indicate degradation of the rod control system.

The controller can be configured to analyze current and voltage measurements of the at least one coil over a plurality of rod movement sequences.

Example embodiments of the present general inventive concept can also be achieved by providing a system to monitor a rod control system of a nuclear power plant, including an impedance determining unit to determine an impedance of at least one coil of a rod movement mechanism during a rod movement sequence of the rod control system during operation of the nuclear power plant, and a controller to record a plurality of impedance calculations over a period of time, and to determine whether a current recorded impedance changes relative to a prior recorded impedance by a predetermined amount to indicate degradation of the rod control system.

### BRIEF DESCRIPTION OF THE DRAWINGS

The following example embodiments are representative of example techniques and structures designed to carry out the objects of the present general inventive concept, but the present general inventive concept is not limited to these example embodiments. In the accompanying drawings and illustrations, the sizes and relative sizes, shapes, and qualities of lines, entities, and regions may be exaggerated for clarity. A wide variety of additional embodiments will be more readily understood and appreciated through the following detailed description of the example embodiments, with reference to the accompanying drawings in which:

FIG. 1 is a schematic block diagram of a rod position control system for a pressurized water reactor according to an example embodiment of the present general inventive concept;

FIG. 2 is a cross sectional block diagram of a Control Rod Drive Mechanism (CRDM) system according to an example embodiment of the present general inventive concept;

FIG. 3 is a cross sectional block diagram of a Control Element Drive Mechanism (CEDM) according to an example embodiment of the present general inventive concept;

FIG. 4 is a block schematic diagram of a rod control system for a CRDM according to an example embodiment of the present general inventive concept;

FIG. 5 is a diagram of an embodiment of lift coil voltage and current during one step of a CRDM rod movement according to an example embodiment of the present general inventive concept;

FIG. 6 illustrates diagrams of an equivalent electrical circuit of a CRDM coil according to an example embodiment of the present general inventive concept.

### DETAILED DESCRIPTION

Reference will now be made to example embodiments of the present general inventive concept, examples of which are illustrated in the accompanying drawings and illustrations. The example embodiments are described herein in order to explain the present general inventive concept by referring to the figures.

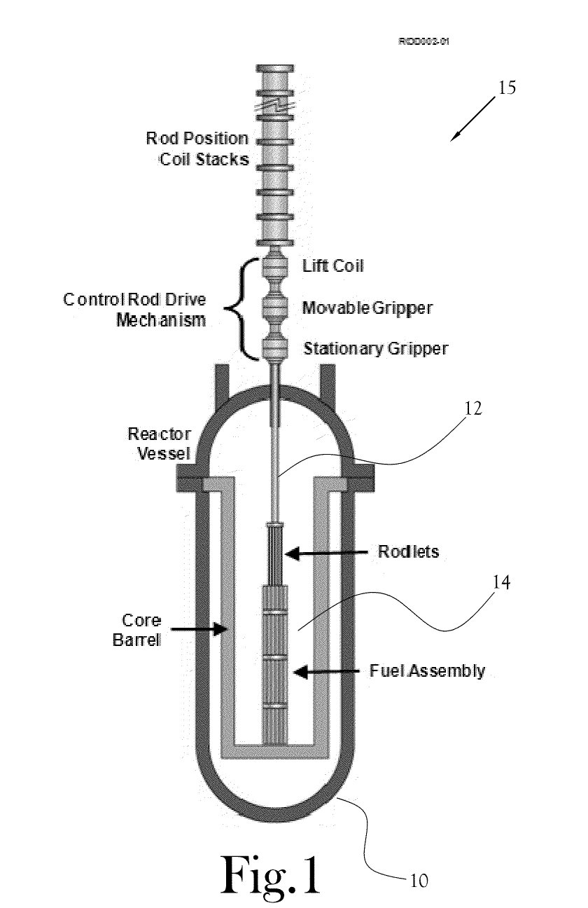

FIG. 1 is a schematic block diagram of a rod position control system 15 for a pressurized water reactor according to an example embodiment of the present general inventive concept. Referring to FIG. 1, the power level of the reactor 10 is controlled by inserting and retracting control rods 12 (which may include the shutdown rods) into the reactor core 14 to control the reactivity by absorbing neutrons. Movement of each rod may be facilitated by its own electromechanical magnetic jack mechanism located atop a reactor vessel referred to as a rod control system. (15)

In the embodiment of FIG. 1, the control rods are moved by a Control Rod Drive Mechanism (CRDM) including electromechanical jacks to raise or lower the control rods in increments. The CRDM may include a lift coil, a moveable coil, and a stationary coil controlled by a Rod Control System (RCS), and a ferromagnetic drive rod coupled to the control rod to move within a pressure housing 16. The drive rod may include a number of circumferential grooves at intervals (“steps”) that define a range of movement for the control rod. An example interval may be ⅝ inch. An example drive rod may contain approximately 231 grooves, which may vary. A moveable gripper mechanically engages the grooves of a drive rod when its coil is energized, and disengages from the drive rod when the coil is de-energized. Energizing a lift coil raises the moveable gripper and the associated control rod if the moveable coil is energized by one step. Energizing the moveable coil and de-energizing the lift coil moves the control rod down one step. Similarly, when energized, a stationary gripper engages the drive rod to maintain the position of the control rod and, when de-energized, disengages from the drive rod to allow the control rod to move. The RCS may include a logic cabinet and a power cabinet. The logic cabinet may receive manual demand signals from an operator or automatic demand signals from a reactor control and provides command signals needed to operate shutdown and control rods according to a predetermined schedule. The power cabinet provides a programmed current.

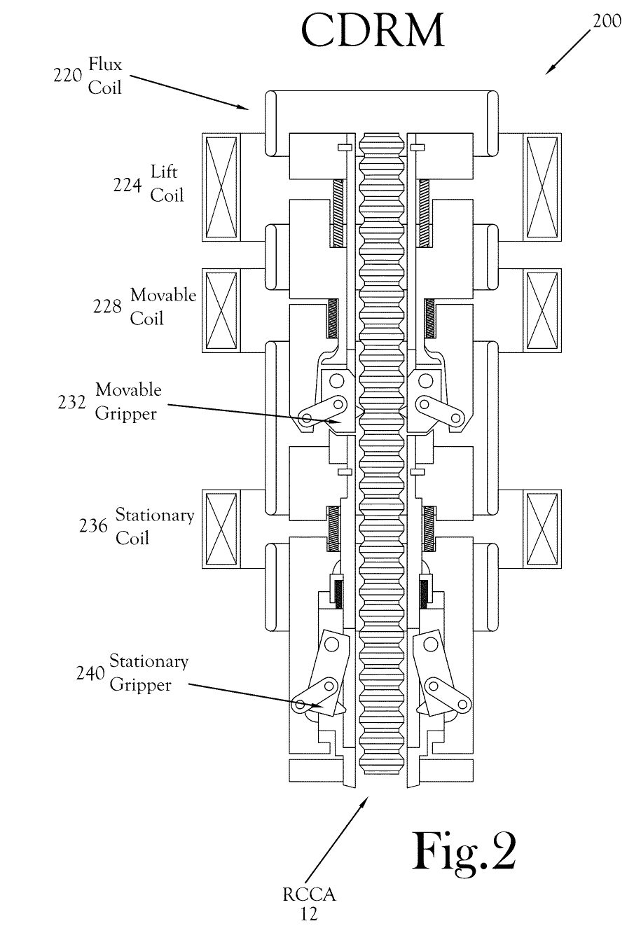

FIG. 2 is a cross sectional block diagram of a Control Rod Drive Mechanism (CRDM) system according to an example embodiment of the present general inventive concept. As illustrated in FIG. 2, an example CRDM comprises three electric coils (Lift, Movable and Stationary) and two electromagnetic jacks with grippers (Movable and Stationary). The drive rod is grooved which allows the grippers to engage and support the weight of the rod. These grooves allow the mechanism to insert and withdraw the rod in a single step.

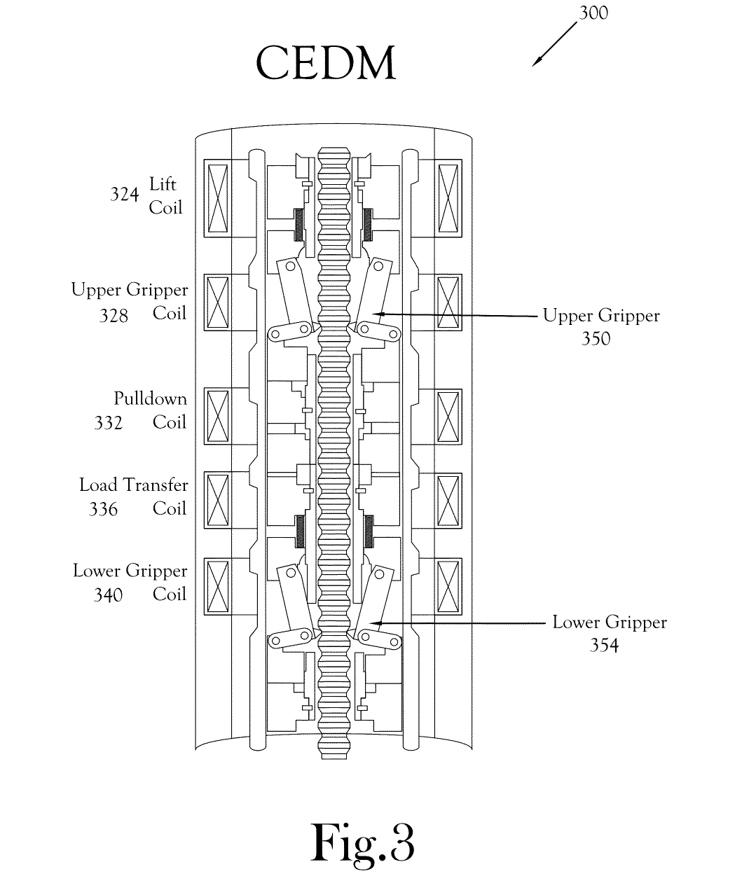

FIG. 3 is a cross sectional block diagram of a Control Element Drive Mechanism (CEDM) according to an example embodiment of the present general inventive concept. As illustrated in FIG. 3, an example CEDM design comprises five electric coils (Lift, Upper Gripper, Pull down, Load Transfer, and Lower Gripper) and two electromagnetic jacks with grippers (Upper and Lower). The drive rod for this system is grooved to allow the rod to insert or withdraw from the reactor core in a single step when the coils are energized in a particular sequence. The sequencing is established by the logic cabinet through a set of current orders which are provided to the power cabinet firing and regulation cards for low, reduced, or full levels of current to be applied to the coils.

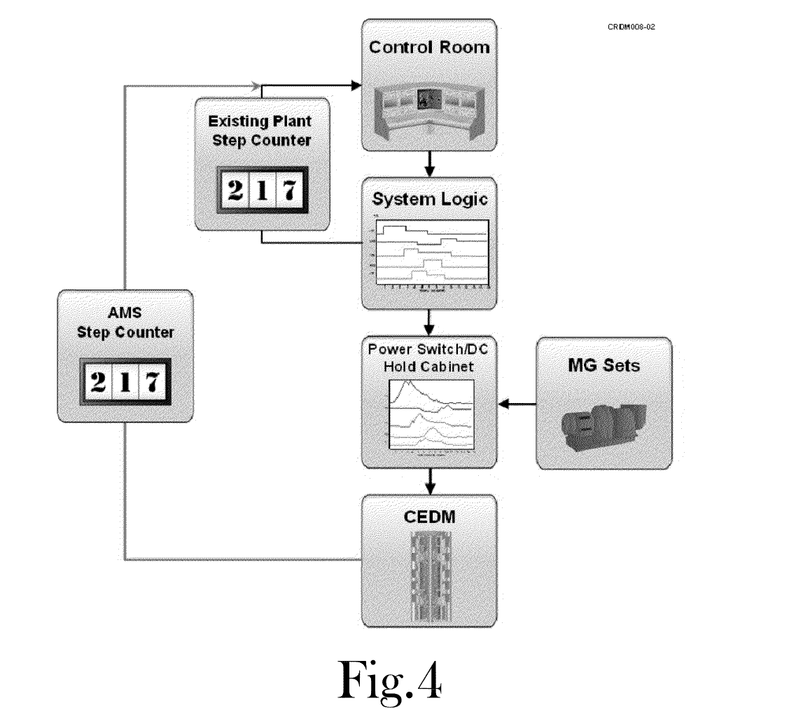

FIG. 4 is a block schematic diagram of a rod control system for a CRDM according to an example embodiment of the present general inventive concept. Referring to FIG. 4, an example rod control system comprises controls and indicators in the main control room, control logic cabinets, power switching cabinets, power distribution from the motor generator sets, and the rod control mechanism itself. The rod movement demand, generated by either the operator or the reactor control system, is received and processed by the cabinet logic. The logic cabinet then controls the power switching circuitry that is responsible for the motion of the rod control mechanism. There are currently three different power levels that the switching circuitry provides to the drive mechanism. These power levels include the ‘High’ state, which is used to quickly energize the coil, ‘Reduced’, which is used to maintain the energized state, and ‘Low’, which is used for the coil in the off state. The logic cabinet is responsible for providing the sequence at which these power levels should be applied to the coils for the desired rod movement.

Example systems and methods of the present general inventive concept can be used to make non-intrusive impedance measurements on rod control system coils in-situ. Coil signal measurements such as coil voltage and coil current can be acquired from existing plant test points.

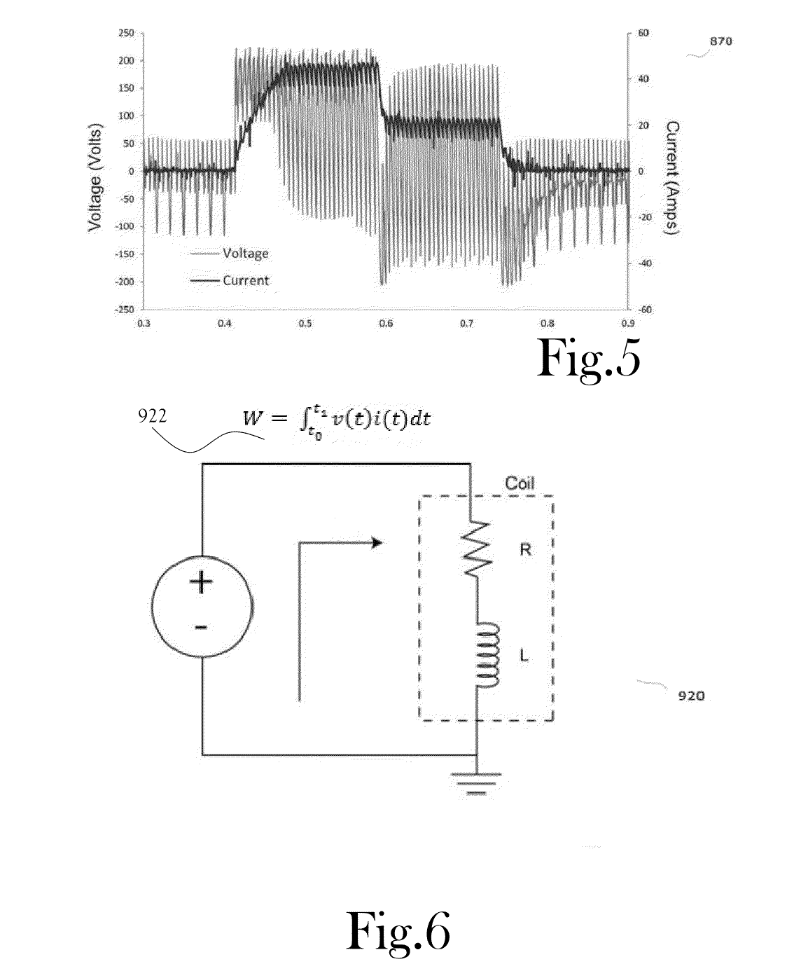

FIG. 5 illustrates an example graph 870 of measured voltage and current applied to a lift coil over time during one step of a CRDM movement cycle according to an example embodiment of the present general inventive concept. The relationship of measured voltage and current over time may be utilized to determine coil and cable health. A change in these values may be an indication of a rod movement failure, electrical degradation, or mechanical degradation. Voltage and current measurements may be used in determining coil and cable health in a non-intrusive impedance measurement on the CRDM coils.

FIG. 6 provides an example equivalent electrical circuit 920 of a CRDM coil embodiment according to an example embodiment of the present general inventive concept. The amount work (W) delivered to a coil over a period of time can be calculated using equation 922. In an example, the work can be calculated over a rod movement sequence to detect changes in the amount of energy needed to move the rod. The examples described herein provide a metric which may be utilized to diagnose rod movement problems because the calculation results may be predictable from step to step wherein a significant variation from normal may be noticed because a problem, such improper rod movement, exists. Changes in the level of work can detect problems with the mechanism.

An example method of monitoring a rod control system of a nuclear power plant, comprises calculating impedance of at least one coil of a rod movement mechanism using a non-intrusive method that utilizes existing plant signals, thereby allowing impedance to be calculated in-situ while the rod control system is online. An example for calculating may comprise comparing a measured impedance to a reference impedance; and determining if the measured impedance deviates from the reference impedance value by a predetermined amount to indicate degradations or failures of the rod control system. An example for calculating may comprise analyzing current and voltage signals. An example for calculating may comprise measuring a resistance of at least one of the following: a coil, a cable, and at least one connector and wherein a measured resistance is used to determine the coil temperature of a rod movement mechanism above a reactor core. An example for calculating may comprise measuring an inductance of at least one of the following: a coil, a cable, and at least one connector. An example for calculating may comprise analyzing the impedance of at least one coil. An example reference impedance is based on historical impedance calculations of the at least one coil.

An example method of monitoring a rod control system of a nuclear power plant may comprise: measuring voltage and current signals of at least one coil of a rod movement mechanism while the system is in operation in the plant; recording a plurality of impedance calculations over a period of time; calculating an impedance of the least one coil based on the measured voltage and current signals; and determining whether a current recorded impedance changes relative to a prior recorded impedance by a predetermined amount indicate degradation of the rod control system.

A system to monitor a rod control system of a nuclear power plant, comprising: an impedance measuring unit to measure an impedance of at least one coil of a rod movement mechanism during plant operation using a non-intrusive method for evaluation of the at least one coil; a controller to compare a measured impedance to a reference impedance, and to determine if the measured impedance deviates from the reference impedance value by a predetermined amount to indicate degradation of the rod control system. An example controller is configured to analyze current and voltage measurements of the at least one coil. An example reference impedance is based on historical impedance measurements of the rod movement mechanism during operation of the nuclear power plant.

A example system to monitor a rod control system of a nuclear power plant, comprising: an impedance determining unit to determine an impedance of at least one coil of a rod movement mechanism during plant operation using a non-intrusive method for evaluation of the at least one coil; a controller to record a plurality of impedance calculations over a period of time, and to determine whether a current recorded impedance changes relative to a prior recorded impedance by a predetermined amount to indicate degradation of the rod control system.

The examples described herein provide a metric which may be utilized to diagnose rod movement problems because the calculation results may be predictable from step to step wherein a significant variation from normal may be noticed because of one or more problems, such as improper rod movement, rod movement failure, electrical degradation, mechanical degradation, etc., exists.

While embodiments of the present general inventive concept are described herein, it is not the intention of the applicant to restrict or in any way limit the scope of the appended claims to such detail. Additional modifications will readily appear to those skilled in the art. The present general inventive concept in its broader aspects is therefore not limited to the specific details, representative apparatus and methods, and illustrative examples shown and described. Accordingly, departures may be made from such details without departing from the spirit or scope of applicant's general inventive concept.

What is claimed is:

1. A method of monitoring a rod control system of a nuclear power plant, comprising:
calculating impedance of at least one coil of a rod movement mechanism using a non-intrusive method that utilizes existing plant signals, thereby allowing impedance to be calculated in-situ while the rod control system is online.

2. The method of claim 1, wherein the calculating comprises comparing a measured impedance to a reference impedance and determining if the measured impedance deviates from the reference impedance value by a predetermined amount to indicate degradations or failures of the rod control system.

3. The method of claim 1, wherein the calculating comprises analyzing current and voltage signals.

4. The method of claim 1, wherein the calculating comprises measuring a resistance of at least one of the following: a coil, a cable, and at least one connector.

5. The method of claim 4, wherein a measured resistance is used to determine the coil temperature of a rod movement mechanism above a reactor core.

6. The method of claim 1, wherein the calculating comprises measuring an inductance of at least one of the following: a coil, a cable, and at least one connector.

7. The method of claim 1, wherein the calculating comprises analyzing the impedance of the at least one coil.

8. The method of claim 2, wherein the reference impedance is based on historical impedance calculations of the at least one coil within a rod movement mechanism.

9. A method of monitoring a rod control system of a nuclear power plant, comprising:
measuring voltage and current signals of at least one coil of a rod movement mechanism while the system is in operation in the plant;
calculating an impedance of the least one coil based on the measured voltage and current signals;
recording a plurality of impedance calculations over a period of time; and
determining whether a current recorded impedance changes relative to a prior recorded impedance by a predetermined amount indicate degradation of the rod control system.

10. A system to monitor a rod control system of a nuclear power plant, comprising:
an impedance measuring unit to measure an impedance of at least one coil of a rod movement mechanism during plant operation using a non-intrusive method for evaluation of the at least one coil;
a controller to compare a measured impedance to a reference impedance, and to determine if the measured impedance deviates from the reference impedance value by a predetermined amount to indicate degradation of the rod control system.

11. The system of claim 10, wherein the controller is configured to analyze current and voltage measurements of the at least one coil.

12. The system of claim 10, wherein the reference impedance is based on historical impedance measurements of the rod movement mechanism during operation of the nuclear power plant.
